(19) United States
(12) Patent Application Publication
(10) Pub. No.: US 2026/0293538 A1
(43) Pub. Date: Sep. 24, 2026

(54) METAL-INSULATOR TRANSITION MATERIAL-BASED MULTIPORT RADIO FREQUENCY SWITCH

(71) Applicant: Dell Products L.P., Round Rock, TX (US)

(72) Inventors: Tejinder Singh, Manotick (CA); Navjot Kaur Khaira, Manotick (CA)

(21) Appl. No.: 19/085,912

(22) Filed: Mar. 20, 2025

(51) Int. Cl. H10N 79/00; H10N 70/00; H10N 70/20

(52) U.S. Cl. CPC H10N 79/00; H10N 70/231; H10N 70/8833

(57) ABSTRACT

The technology described herein is directed towards a phase change material-based (e.g., metal-insulator transition material such as vanadium dioxide) radio frequency (RF) switch device. The switch has phase change material-based switches between the device's ports, in which the phase change material switches are controlled to be in either conductive or nonconductive states, thereby respectively coupling or decoupling any port to any other port, e.g., in different operational states. A controller can selectively output the voltage to heat the material in the respective junctions of respective switches to independently determine their respective conductive or nonconductive states as needed for a specified operational state. In one implementation, the switch design is symmetrical. The example vanadium dioxide material switch described herein provides high switching speeds, low insertion loss, good isolation and is relatively straightforward to fabricate.

### RELATED APPLICATION

The subject patent application is related to U.S. patent application Ser. No. ______, filed ______, entitled “TRANSITION MATERIAL-BASED NON-BLOCKING MULTIPLE STATE, MULTIPORT RADIO FREQUENCY SWITCH” (docket no. 141962.01/DELLP1539US, the entireties of which patent application is hereby incorporated by reference herein.

### BACKGROUND

Radio frequency (RF) switches control the routing of RF signals in communication systems, and are used for tasks like antenna selection and signal path switching. Common types of RF switches include PIN diodes, FET (field effect transistor)/GaN (Gallium Nitride) switches, and MEMS (micro-electromechanical systems) switches, each with unique characteristics in terms of speed, power consumption, and performance.

RF switches are used in devices such as mobile phones, base stations, and phased array antennas for tasks like signal routing, antenna switching, and phase shifting. Important factors for RF switches include insertion loss (signal loss through the switch), isolation (preventing signal leakage between paths), and switching speed (how quickly the switch changes states). Existing RF switches often suffer from at least one of high insertion loss, poor isolation, and/or complex fabrication processes, limiting their applicability in space-constrained high-performance scenarios.

### BRIEF DESCRIPTION OF THE DRAWINGS

The technology described herein is illustrated by way of example and not limited to the accompanying figures in which like reference numerals indicate similar elements and in which:

FIGS. 1 and 2 are a top view representation and a zoomed-in view representation, respectively, showing an example switch layout of a multiport (e.g., four port) radio frequency (RF) switch in which switching is achieved by using vanadium dioxide (VO₂) junctions, in accordance with various embodiments and implementations of the subject disclosure.

FIGS. 3A and 3B are representations of two possible states of the example four port switch, in accordance with various embodiments and implementations of the subject disclosure.

FIG. 4 is a three-dimensional top view of a VO₂-based junction, useable in the example multiport (e.g., four port) switch, in accordance with various embodiments and implementations of the subject disclosure.

FIG. 5 is a top view representation showing a signal path in the example switch from Port 1 to Port 4 based on VO₂ Switch 1 being in a conductive (“closed”) state and VO₂ Switch 2 and Switch 4 being in a nonconductive (“open”) state, in accordance with various embodiments and implementations of the subject disclosure.

FIG. 6 is a three-dimensional (3D) top view representation of an example four port RF switch atop a substrate, in accordance with various embodiments and implementations of the subject disclosure.

FIG. 7 is a two-dimensional (2D) top view representation showing example components of an example four port RF switch being controlled by a controller, in accordance with various embodiments and implementations of the subject disclosure.

FIG. 8 is a 3D view of an alternative VO₂-based switch junction, useable in an example multiport (e.g., four port) switch, in which the heating element is on top, in accordance with various embodiments and implementations of the subject disclosure.

FIG. 9 is a 3D rendered view of an example four port RF switch atop a substrate, in accordance with various embodiments and implementations of the subject disclosure.

FIG. 10 is a 2D top view representation showing simulated surface current density with one switch (Switch 2) actuated (in its conductive state), in accordance with various embodiments and implementations of the subject disclosure.

FIGS. 11A and 11B are graphical representations of simulation results showing return loss and insertion loss (FIG. 11A) and isolation (FIG. 11B) versus signal frequency of an example four port RF switch when either State I or State II is active, in accordance with various embodiments and implementations of the subject disclosure.

FIGS. 12A and 12B are graphical representations of simulation results showing return loss and insertion loss (FIG. 12A) and isolation (FIG. 12B) versus signal frequency of an example four port RF switch when both State I and State II are active, in accordance with various embodiments and implementations of the subject disclosure.

FIGS. 13A, 13B, 13C, 13D, 14A, 14B, 14C, 14D, 15A, 15B, 16A, 16B, 17A and 17B are various 3D and cross-sectional views of an example manufacturing process for a fabricating an example multiport switch, in accordance with various embodiments and implementations of the subject disclosure.

FIGS. 18 and 19 comprise a flow diagram showing example operations related to electrically coupling one or more selectable RF ports to another RF port based on controlling metal-insulator transition material junction states, in accordance with various aspects and implementations of the subject disclosure.

### DETAILED DESCRIPTION

Various implementations and embodiments of the technology described herein are generally directed towards a highly efficient, low power, and compact radio frequency (RF) multiport switch that provides reliable switching performance across multiple states while being cost-effective to manufacture. The multiport switch integrates metal-insulator transition (e.g., vanadium dioxide, or VO₂) material, enabling multistate operation for routing an input signal from any available port to any available free port, such as embodied in a four-port switch with distinct states for flexible signal routing across multiple ports.

In one implementation, the transition material-based switch facilitates multiport RF switching using four series switches designed for reliable RF signal routing, including two distinct operational states. The switch leverages the phase-transition properties of VO₂, namely between conductive and nonconductive states, to enable controllable, efficient RF switching with very low power requirements. The integration of the four series switches enhances control over signal flow, allowing for flexible routing and improved isolation between states.

Note that conventional RF switches face limitations in achieving efficient switching with low power consumption while maintaining robustness in challenging environments. Traditional designs often use complex mechanical structures or bulky components, leading to increased costs and limited scalability. In contrast, the technology described herein provides compact RF switches that can provide reliable switching performance across multiple states while being cost-effective to manufacture; the VO₂-based switch meets desirable performance criteria while being straightforward to fabricate on a large scale.

It should be understood that any of the examples and/or descriptions herein are non-limiting. Thus, any of the embodiments, example embodiments, concepts, structures, functionalities or examples described herein are non-limiting, and the technology may be used in various ways that provide benefits and advantages in communications and computing in general.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some practical limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

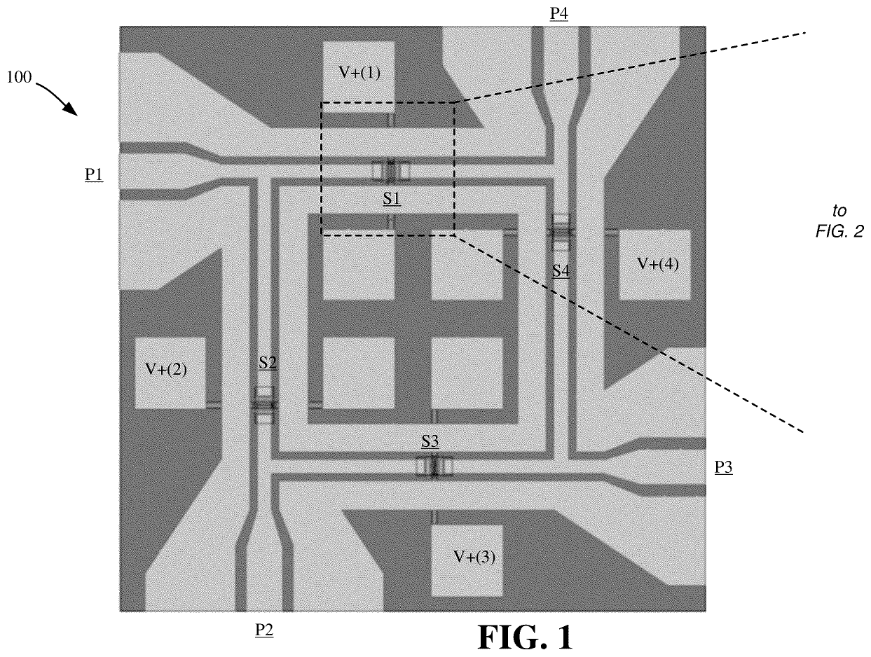

FIG. 1 shows an example top-view of one implementation of a four-port multiport switch (device) 100, including ports P1-P4 and four switches S1-S4. The switch 100 includes four bias pads (contact terminals) V+(1) through V+(4) and corresponding bias lines for selectively applying voltage (or current) to switch heating elements of a heater network and thereby control the conductive or nonconductive states of the VO₂ material as described herein, e.g., one VO₂ material junction per switch.

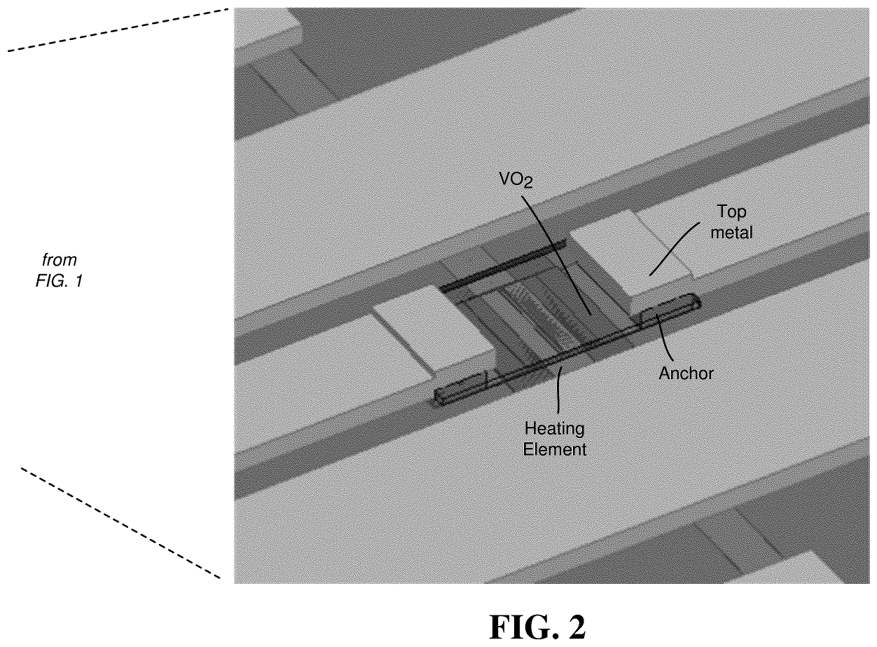

FIG. 2 is a three-dimensional (3D) zoomed-in view of the switch 1 (S1) part of the four-port multiport switch 100 of FIG. 1. A heating element is present to controllably heat the VO₂ material to change the switch junction to its conductive state. The switch is anchored underneath a top metal layer as described herein.

Note that traditional RF switch designs have predominantly relied on mechanical-based switches, semiconductors, or coaxial relays, each with distinct limitations. Certain technologies provide compactness but suffer from reliability issues and complex fabrication processes. Semiconductor switches offer faster switching but tend to have higher insertion loss and limited isolation. Mechanical relays, while robust, are bulky and costly, limiting their applicability in space-constrained environments.

In contrast, described herein are VO₂-based switches that overcome traditional RF switch limitations. In general, VO₂ material exhibits a temperature-induced phase transition around 67° C. Below this temperature, VO₂ acts as an insulator (high resistivity). As the temperature rises above this threshold, VO₂ transitions into a metallic phase (low resistivity). The insulator-to-metal phase transition in VO₂ occurs at ultrafast speed, on the order of a few femtoseconds (fs). Note that the technology described herein is not limited to any particular phase change material, and, for example, other metal-insulator transition materials such as vanadium trioxide or vanadium pentoxide can be used, as long as the phase can be controllably, reliably, and relatively quickly changed.

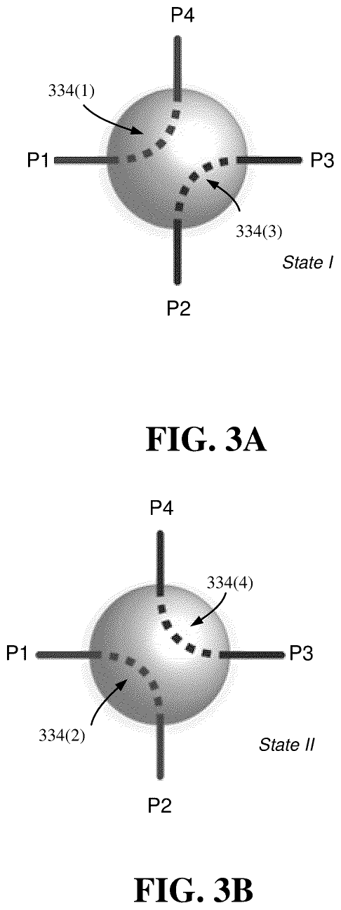

FIGS. 3A and 3B show example operational non-blocking connection states, state I and state II, respectively. As can be seen, in FIG. 3A (state I), the conductive or nonconductive state of the switch 334(1) determines whether port P1 is electrically coupled to or decoupled from port P4. Similarly, the conductive or nonconductive state of the switch 334(3) determines whether port P2 is electrically coupled to or decoupled from port P3. Both connections are independent yet can be simultaneous by actuating both switches 334(1) and 334(3).

In FIG. 3B (state II), the conductive or nonconductive state of the switch 334(2) determines whether port P1 is electrically coupled to or decoupled from port P2, while the conductive or nonconductive state of the switch 334(4) determines whether port P3 is electrically coupled to or decoupled from port P4. Both connections are independent yet can be simultaneous by actuating both switches 334(2) and 334(4).

Thus, an example 4-port switch is designed with two operational states I and II. The design is based on symmetrical T-split, and can route signals between port 1 to 4 and/or port 2 to 3, including at the same time, considered as state I of the device. A signal routed between port 1 to 2 and/or port 3 to 4, which can be simultaneously, is considered as state II. Note that additional states are feasible by adding more switches. The example implementation shows a symmetrical, ninety-degree RF design so as to offer substantially identical performance regardless of which port is considered as input or output. The RF performance of the switches is almost similar, as the signal losses usually come from switches and junctions itself. Note that a single path provides somewhat better performance relative to having two paths connected at the same time.

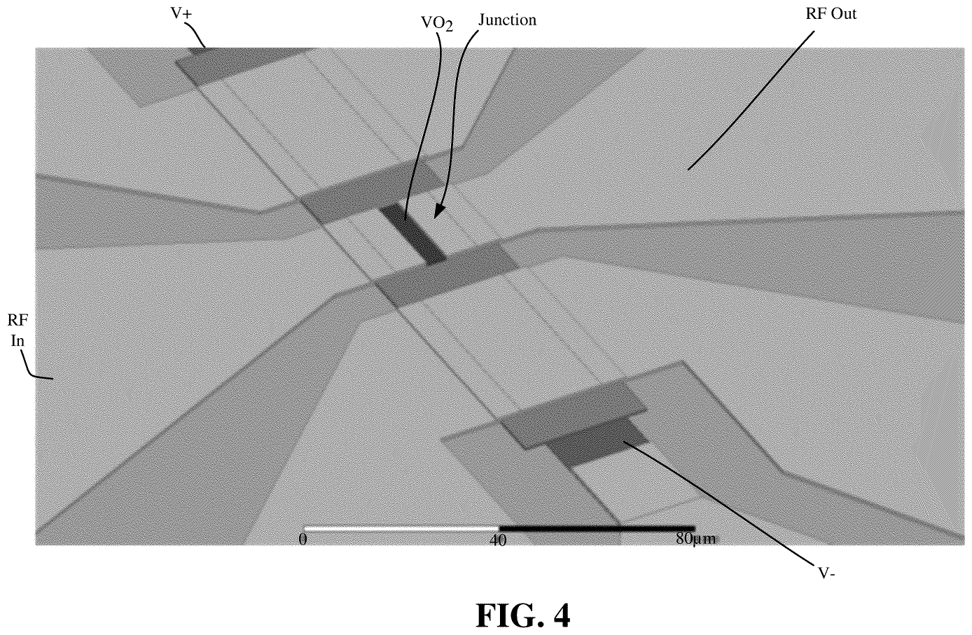

FIG. 4 shows switch components of an example switch useable in the multiport switch described herein. As can be seen, VO₂ material is present in the switch junction, with a heating element underneath that heats up when voltage bias V+ to V− is applied thereto for actuation. The conductors for RF In and RF output ports are also shown, which as can be readily appreciated, only provides a signal path when the VO₂ material is heated above the transition temperature to its conductive state. FIG. 4 shows some example dimensions in micrometers (μm).

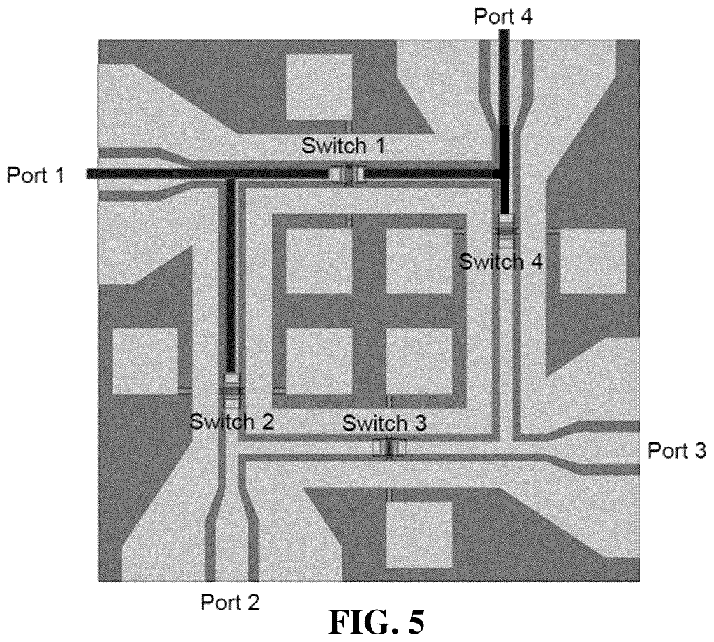

FIG. 5 shows a signal path (the dark line) between port 1 to port 4 when switch 1 is actuated, and switch 2 and switch 4 are de-actuated to block the signal from going elsewhere (e.g., for non-blocking switching so that signals on port 1 are not coupled to port 2, nor signals at port 4 coupled to port 3). This corresponds to one part of State I; the other part of State I would be to couple port 2 to port 3 by actuating switch 3. State II operates similarly, but is not depicted herein for purposes of brevity.

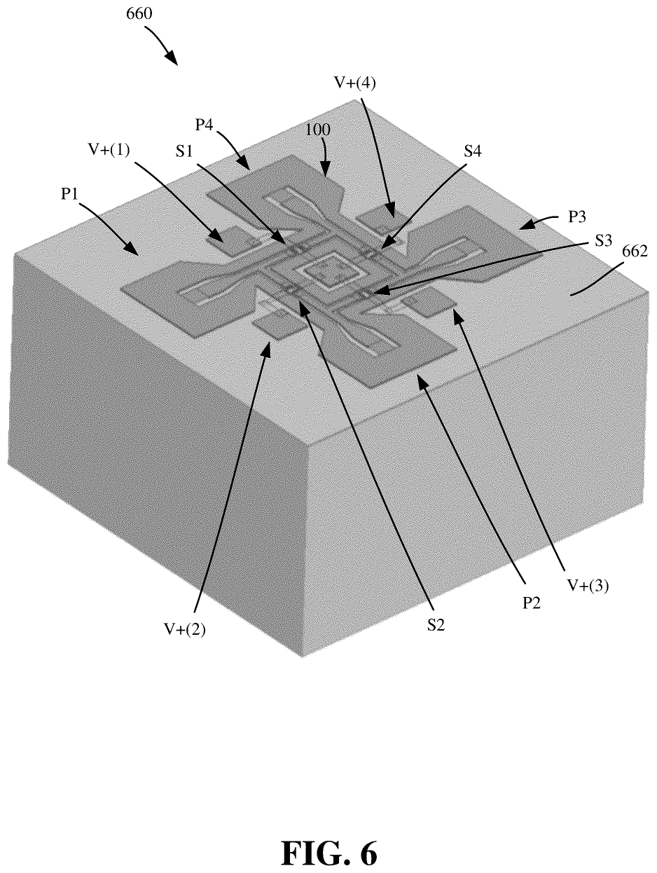

FIG. 6 shows a 3D view of a device 660 in which the multiport switch is fabricated above a substrate 662. The components labeled in FIG. 1 are similarly labeled in FIG. 6.

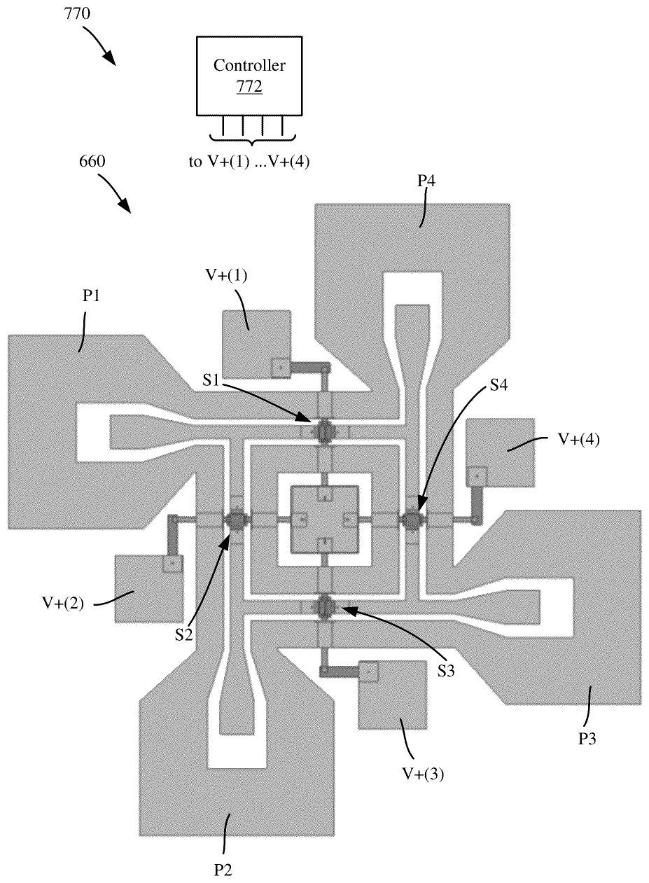

FIG. 7 shows a top 2D view of the switch 660 (minus the substrate) implemented in a system 770 that includes a controller 772. The controller 772 selectively applies voltage to one or more of the voltage pads V+(1), V+(3) and/or V+(4) to selectively couple ports to one another.

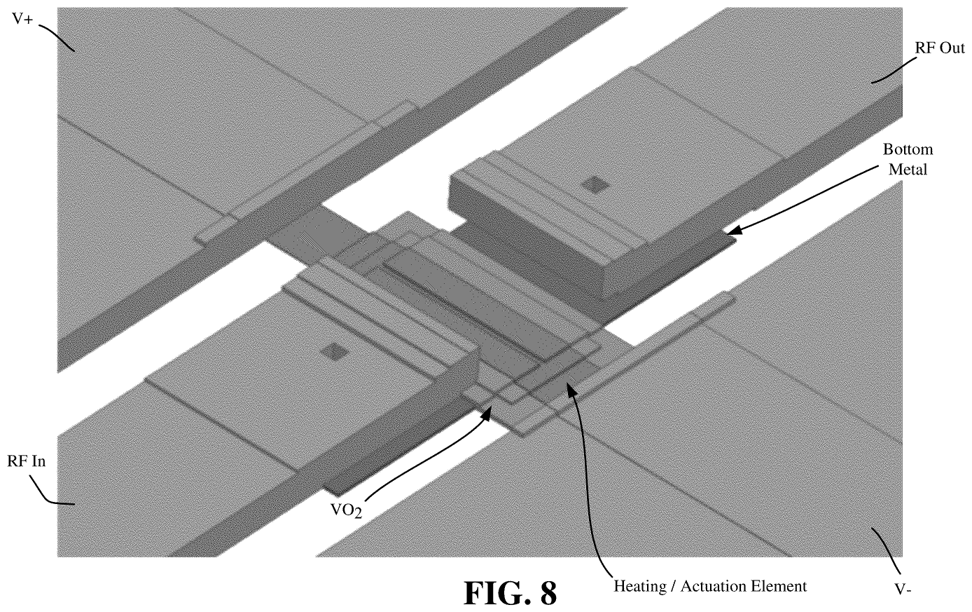

FIG. 8 shows switch components of an example switch useable in the multiport switch described herein. Similar to FIG. 4, VO₂ material is present in the switch junction, with a heating element that heats up when voltage bias V+ to V− is applied thereto for actuation. In an alternative to the design of FIG. 4, in FIG. 8 the heating element is on top. The conductors for RF In and RF output ports are also shown, which as can be readily appreciated, only provides a signal path when the VO₂ material is heated above the transition temperature to its conductive state.

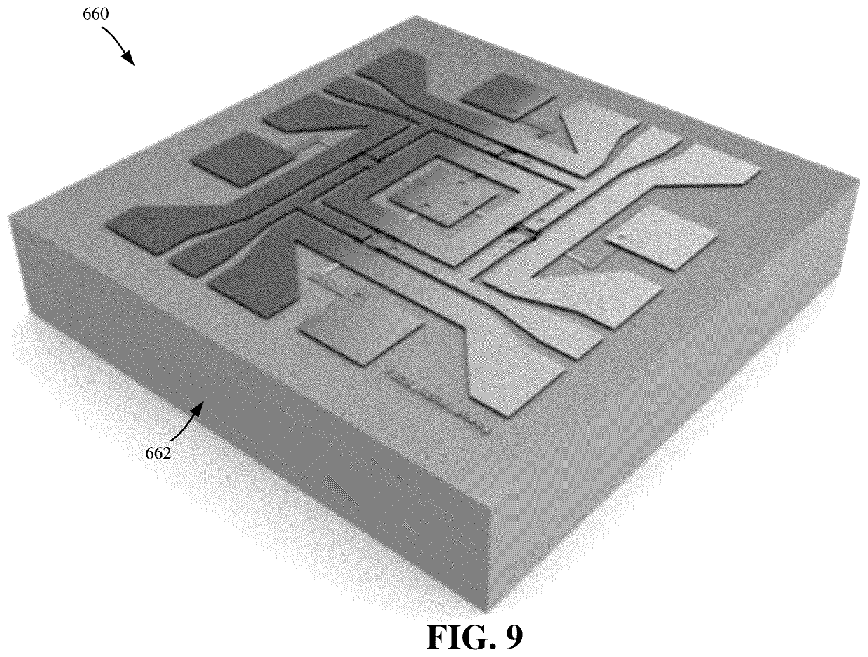

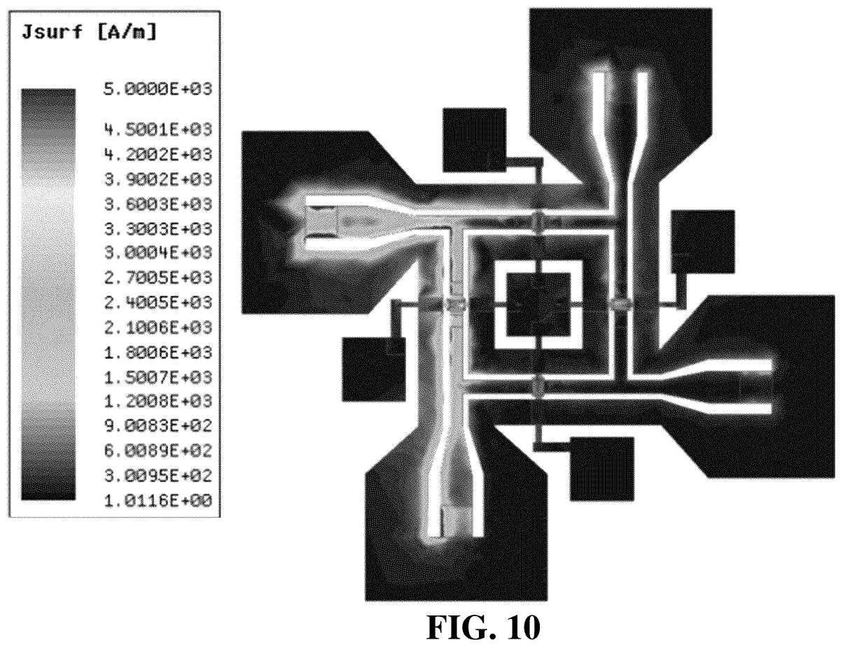

FIG. 9 is a 3D rendered view of an example four port RF switch atop a substrate, suitable for use in simulations. FIG. 10 is a 2D top view representation showing simulated surface current density with one switch (Switch 2) actuated (in its conductive state), along with surface current density values in amperes per meter (A/M).

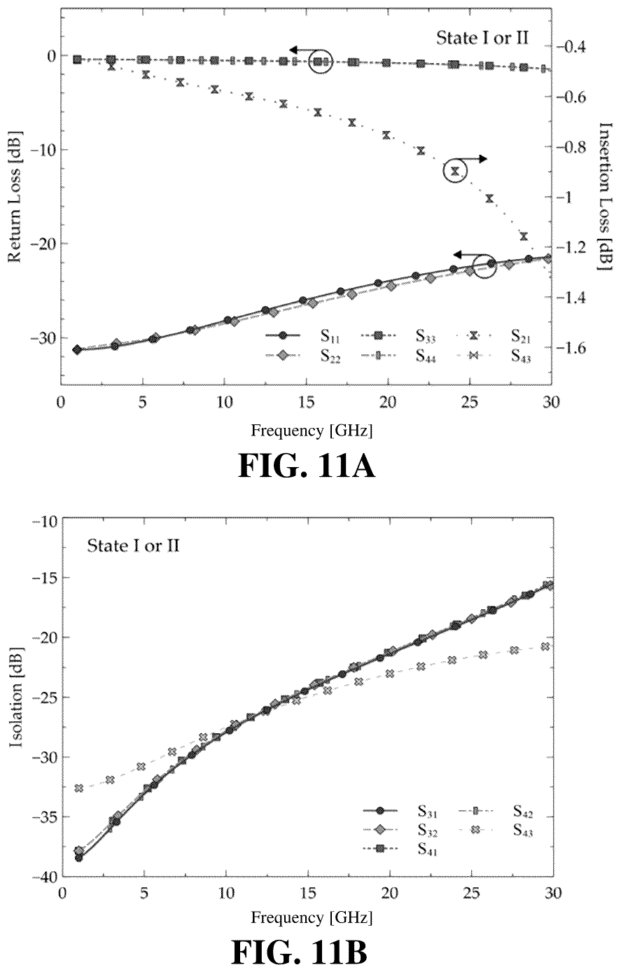

FIG. 11A is a graphical representation of simulation results showing return loss and insertion loss in dB for varying signal frequency when either State I or State II is active. FIG. 11B graphically represents the corresponding isolation.

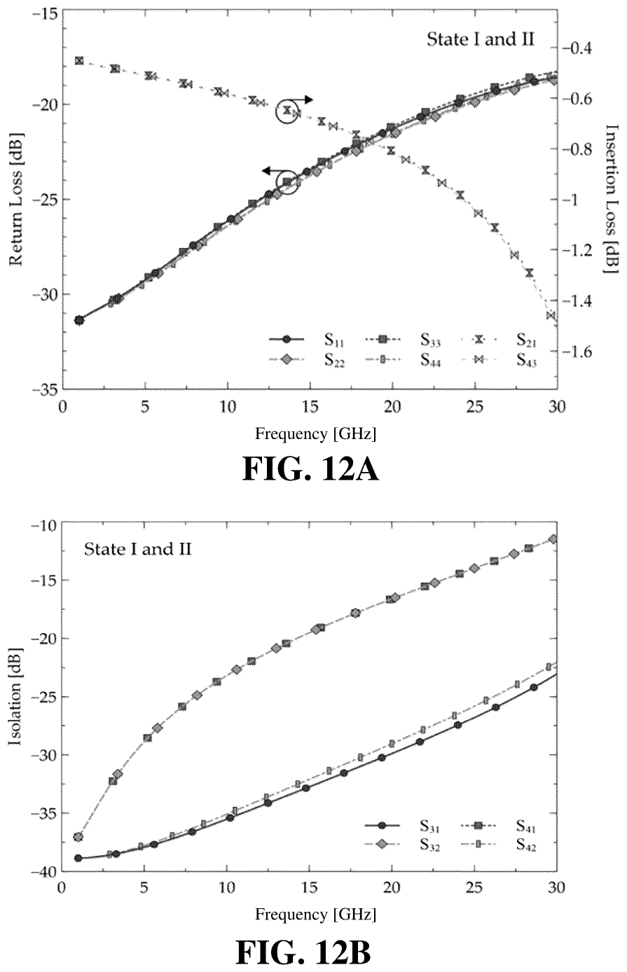

FIG. 12A is a graphical representation of simulation results showing return loss and insertion loss in dB for varying signal frequency when both State I and State II are active. FIG. 12B graphically represents the corresponding isolation.

A detailed manufacturing process has been developed to optimize the production of the example VO₂-based RF switch, facilitating scalability and consistent performance. This example design and process, described herein, is suitable for high-performance RF applications, balancing efficiency, durability, and manufacturability. Note that the materials described with reference to the manufacturing process are nonlimiting examples, and that other suitable materials can be substituted as appropriate for a given application.

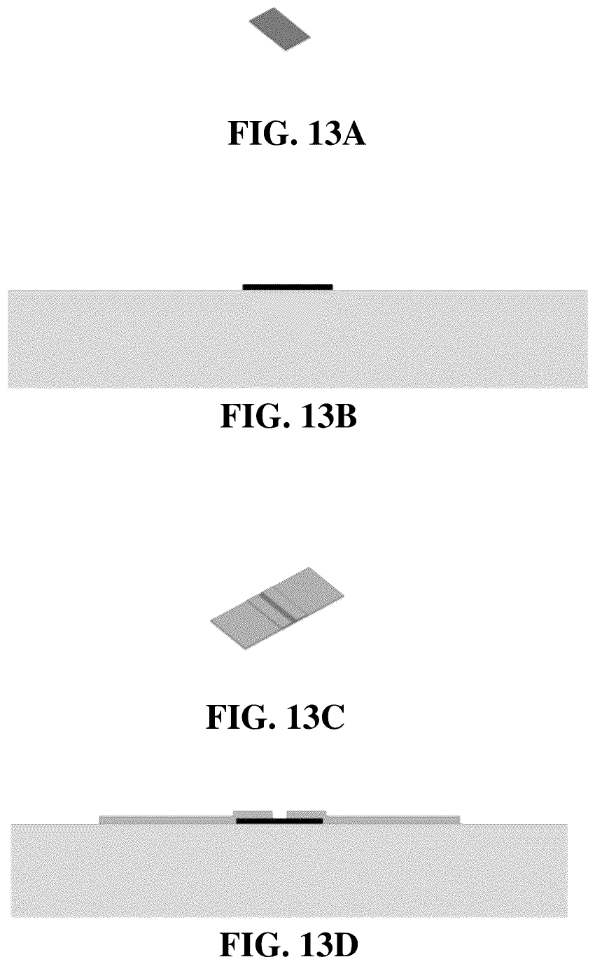

A first step, shown in FIGS. 13A (3D view) and 13B (cross-sectional view), is to deposit phase change material (e.g., VO₂ or germanium telluride), e.g., 250 nanometers (nm), on a substrate. FIGS. 13C and 13D show a first gold layer (or other suitable metal such as aluminum, copper and so on) added as a mask (Cr+Au 100+250 nm).

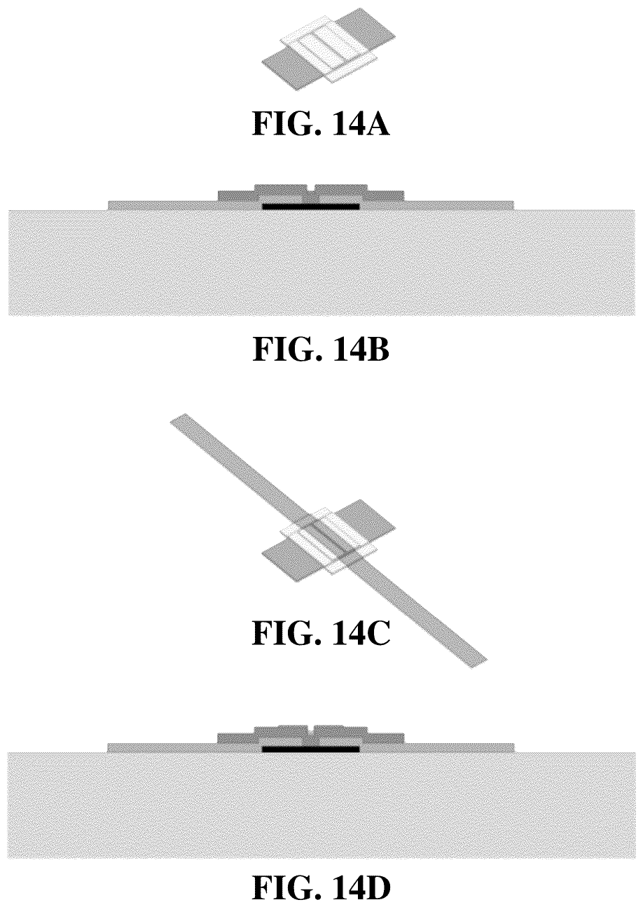

FIGS. 14A and 14B add silicon nitride as an insulator and heat transferring material, e.g., 500 nm. A next step, shown in FIGS. 14C and 14D, adds a NiChrome (nickel and chromium, e.g., 50 nm) as a heater/heating element.

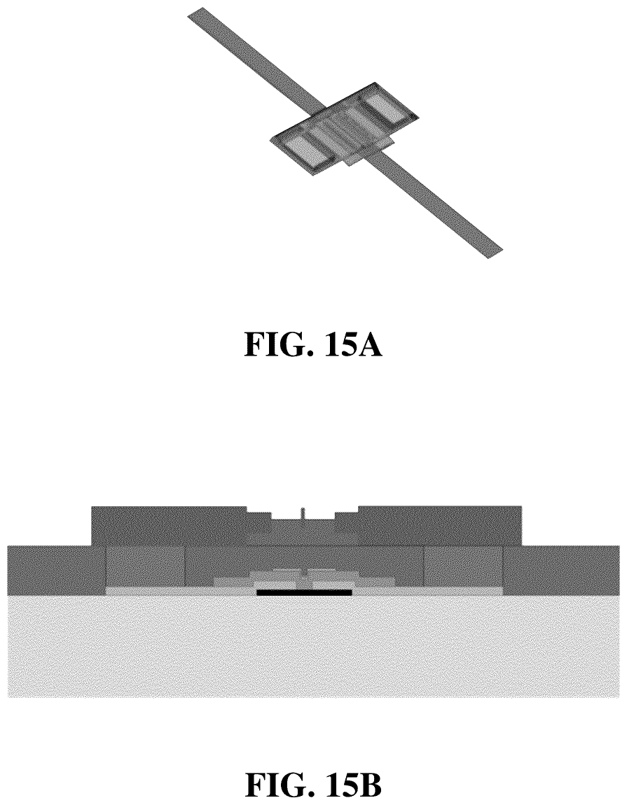

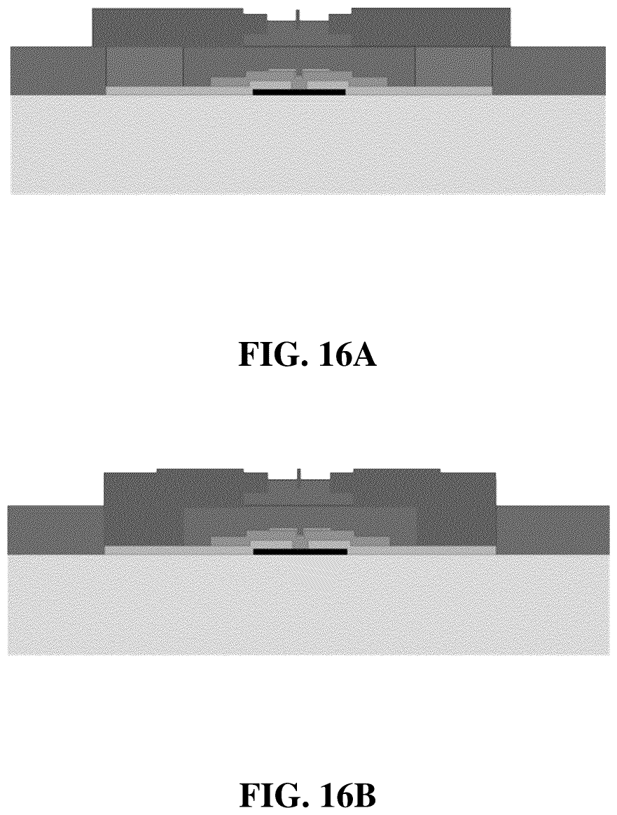

A next step, shown in FIGS. 15A and 15B, adds polyimide/passivation layer, e.g., 2.5 um. Anchors are added as in FIGS. 16A and 16B.

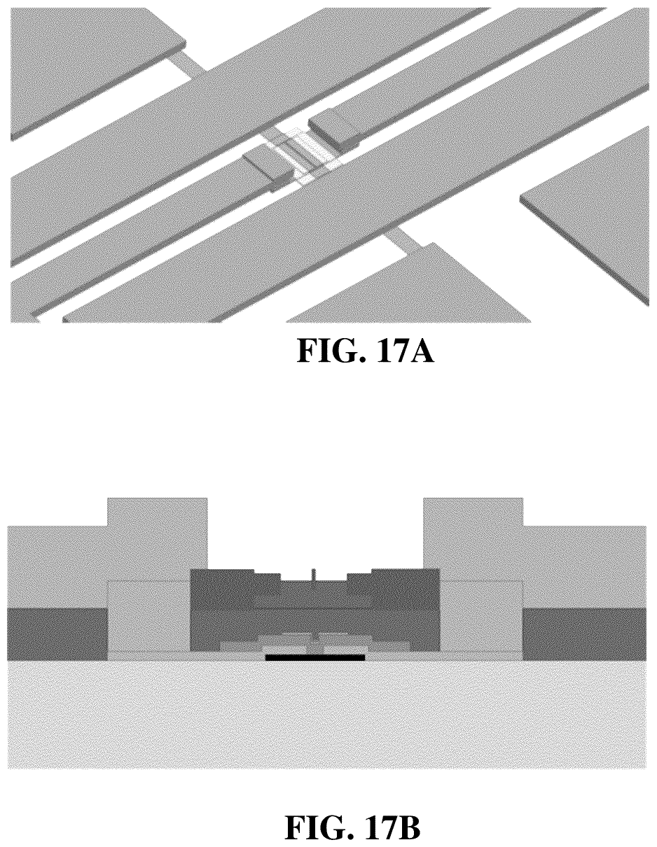

A second gold (or other metal) layer is added as a next step, e.g., 4 um of electroplated Au, as shown in FIGS. 17A and 17B. note that in FIG. 17A, the polyimide and substrate are not shown.

One or more implementations can be embodied in a device. The device can include a multiport radio frequency (RF) switch, including RF ports, respective selective metal-insulator transition material switches coupled to the RF ports, and a controllable heater network including respective heating elements that transfer heat to the respective selective metal-insulator transition material switches, the controllable heater network being selectively controlled to output heat energy to operate the RF multiport switch in an operational state in which a first switch of the respective metal-insulator transition material switches is controlled to be to a conductive state that electrically couples a first RF port of the RF ports to a second RF port of the RF ports.

The operational state can further electrically couple a third RF port of the RF ports to a fourth RF port of the RF ports.

The operational state can be a first operational state, and the controllable heater network can be selectively controllable to output heat energy to operate the RF switch in a second operational state in which the first RF port can be electrically coupled to a fourth RF port of the RF ports.

The second operational state can further electrically couple the second RF port of the RF ports to a third RF port of the RF ports.

The second operational state further electrically decouple the first RF port from the second RF port.

The RF ports can be symmetrically distributed relative to a center point of the RF switch.

The respective metal-insulator transition material switches can be symmetrically distributed relative to a center point of the RF switch.

The RF ports can include a set of four RF ports, a set of eight RF ports, or a set of sixteen RF ports.

Each of the metal-insulator transition material switches can include at least one of: vanadium trioxide, vanadium dioxide, or vanadium pentoxide.

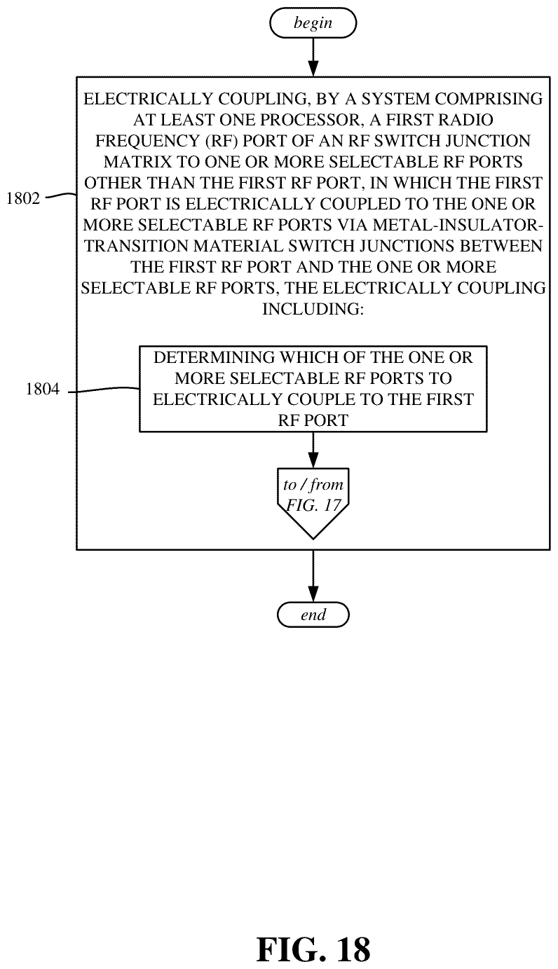

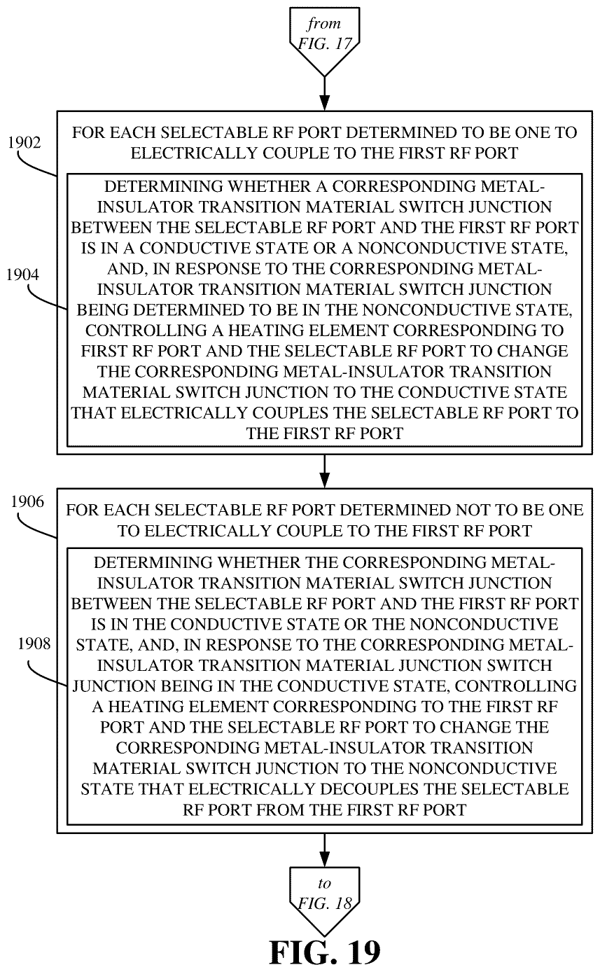

One or more example embodiments, implementations, and/or operations, such as corresponding to example operations of a method, can be represented in FIGS. 18 and 19. Example operation 1802 of FIG. 18 represents electrically coupling, by a system comprising at least one processor, a first radio frequency (RF) port of an RF switch junction to one or more selectable RF ports other than the first RF port, wherein the first RF port can be electrically coupled to the one or more selectable RF ports via metal-insulator transition material switch junctions between the first RF port and the one or more selectable RF ports, the electrically coupling can include example operation 1804, and example operations 1902, 904,1906 and 1908 of FIG. 19. Example operation 1804 represents determining which of the one or more selectable RF ports to electrically couple to the first RF port. The process continues at example operation 1902 of FIG. 19, which represents, for each selectable RF port determined to be one to electrically couple to the first RF port, determining whether a corresponding metal-insulator transition material switch junction between the selectable RF port and the first RF port can be in a conductive state or a nonconductive state, and, in response to the corresponding metal-insulator transition material switch junction being determined to be in the nonconductive state, controlling a heating element corresponding to first RF port and the selectable RF port to change the corresponding metal-insulator transition material switch junction to the conductive state that electrically couples the selectable RF port to the first RF port (example operation 1904). Example operation 1906 represents, for each selectable RF port determined not to be one to electrically couple to the first RF port, determining whether the corresponding metal-insulator transition material switch junction between the selectable RF port and the first RF port can be in the conductive state or the nonconductive state, and, in response to the corresponding metal-insulator transition material junction switch junction being in the conductive state, controlling a heating element corresponding to the first RF port and the selectable RF port to change the corresponding metal-insulator transition material switch junction to the nonconductive state that electrically decouples the selectable RF port from the first RF port (example operation 1908).

Controlling the heating element can include applying a first voltage to the heating element to change the corresponding metal-insulator transition material switch junction to the conductive state, or applying a second voltage to the heating element to change the corresponding metal-insulator transition material junction to the nonconductive state; the second voltage can be reduced relative to the first voltage.

Determining which of the one or more selectable RF ports to electrically couple to the first RF port can include determining that the second RF port is to electrically couple to the first RF port, the heating element corresponding to first RF port and the second RF port can include a first heating element, a metal-insulator transition material switch junction corresponding to the first RF port can be a first metal-insulator transition material switch junction in a first conductive state, and further operations can include controlling, by the system, a second heating element corresponding to a third RF port and a fourth RF port to change a second metal-insulator transition material switch junction to a second conductive state that electrically couples the third RF port to the fourth RF port.

A metal-insulator transition material switch junction corresponding to the first RF port can be a first metal-insulator transition material switch junction in a first conductive state, the electrically coupling can be a first electrically coupling operation in which the determining of which of the one or more selectable RF ports to electrically couple to the first RF port can include determining that the second RF port can be to electrically couple to the first RF port, and, in a second electrical coupling operation, the determining which of the one or more selectable RF ports to electrically couple to the first RF port can include determining that the fourth RF port can be to electrically couple to the first RF port, the heating element corresponding to the first RF port and the fourth RF port can include a second heating element. Further operations can include controlling, by the system, the first heating element corresponding to the first RF port and the second RF port to change the first metal-insulator transition material switch junction to the first nonconductive state that electrically decouples the first RF port from the second RF port, and controlling, by the system, the second heating element to change a second metal-insulator transition material switch junction to a second conductive state that electrically couples the first RF port to the fourth RF port.

The first RF port can be an input port that obtains an input signal, and the electrically coupling can include determining at least one of the one or more selectable RF ports as at least one corresponding output port usable to obtain the input signal.

The first RF port can be an output port, and further comprising determining, by the system, a single selectable RF port of the one or more selectable RF ports to be an input port that obtains an input signal; the electrically coupling can couple the single selectable RF port to the first RF port.

The electrically coupling can be a first electrically coupling operation that can couple the first RF port to a fourth RF port of the one or more selectable RF ports via a first metal-insulator transition material switch junction, of the metal-insulator transition material switch junctions, in a first conductive state, can decouple the first RF port from at least one of: a second RF port of the one or more selectable RF ports, or a third RF port of the one or more selectable RF ports, and further operations can include in a second electrically coupling operation, electrically coupling, by the system, the second RF port to the third RF port via controlling a second heating element associated with a second metal-insulator transition material switch junction, of the metal-insulator transition material switch junctions, corresponding to the second RF port and the third RF port to change the second metal-insulator transition material switch junction to a second conductive state that electrically couples the second RF port to the third RF port.

One or more implementations can be embodied in a multiport switch. The multiport switch can include a group of radio frequency (RF) ports comprising a first port, a second port, a third port, and a fourth port, and respective metal-insulator transition material switches corresponding to the group of RF ports, the respective metal-insulator transition material switches comprising a first switch, a second switch, a third switch, and a fourth switch. The multiport switch can include a controllable heater network that can include respective heating elements that transfer heat to the respective metal-insulator transition material switches, the controllable heater network able to be controlled to output heat via energy to selectively determine respective lower resistance states or respective higher resistance states of the respective metal-insulator transition material switches. The controllable heater network can be controlled to at least one of: set a first switch state to electrically couple the first RF port to the second RF port, set a second switch state to electrically couple the first RF port to the fourth RF port, set a third switch state to electrically couple the second RF port to the third RF port, or set a fourth switch state to electrically couple the third RF port to the fourth RF port.

The respective metal-insulator transition material switches can be arranged in a substantially rectangular pattern.

The group of RF ports can be arranged in a substantially rectangular pattern, and signal path length between any two electrically coupled RF ports can be substantially equal.

The first RF port can be electrically coupled to the second RF port, and the controllable heater network can be further controlled to electrically decouple the first RF port from the fourth RF port.

As can be seen, the technology described herein facilitates an ultracompact multiport switch that includes a (e.g., a four) series switch configuration based on phase-change alloy/metal-insulator transition material (e.g., VO₂) technology. The inclusion of four series switches offers improved control over signal routing and state isolation, adding flexibility in operational modes. In a non-blocking state, the design provides two distinct operational states, allowing for versatile signal routing with minimal power consumption. The technology described herein also includes an example dedicated manufacturing process, developed to facilitate scalability, ensuring consistent switch performance and enabling cost-effective mass production. The result is a multiport switch with a compact and efficient design for RF applications; by focusing on compactness and operational efficiency, the switch design presents a solution for space-constrained, high-performance RF environments.

What has been described above include mere examples. It is, of course, not possible to describe every conceivable combination of components, materials or the like for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
a multiport radio frequency (RF) switch, comprising:
RF ports;
respective selective metal-insulator transition material switches coupled to the RF ports; and
a controllable heater network comprising respective heating elements that transfer heat to the respective selective metal-insulator transition material switches, the controllable heater network being selectively controlled to output heat energy to operate the RF switch in an operational state in which a first switch of the respective metal-insulator transition material switches is controlled to be to a conductive state that electrically couples a first RF port of the RF ports to a second RF port of the RF ports.

2. The device of claim 1, wherein the operational state further electrically couples a third RF port of the RF ports to a fourth RF port of the RF ports.

3. The device of claim 1, wherein the operational state is a first operational state, and wherein the controllable heater network is selectively controllable to output heat energy to operate the RF switch in a second operational state in which the first RF port is electrically coupled to a fourth RF port of the RF ports.

4. The device of claim 3, wherein the second operational state further electrically couples the second RF port of the RF ports to a third RF port of the RF ports.

5. The device of claim 4, wherein the second operational state electrically decouples the first RF port from the second RF port.

6. The device of claim 1, wherein the RF ports are symmetrically distributed relative to a center point of the RF switch.

7. The device of claim 1, wherein the respective metal-insulator transition material switches are symmetrically distributed relative to a center point of the RF switch.

8. The device of claim 1, wherein the RF ports comprise a set of four RF ports, a set of eight RF ports, or a set of sixteen RF ports.

9. The device of claim 1, wherein each of the metal-insulator transition material switches comprises at least one of: vanadium trioxide, vanadium dioxide, or vanadium pentoxide.

10. A method, comprising:
electrically coupling, by a system comprising at least one processor, a first radio frequency (RF) port of an RF switch junction to one or more selectable RF ports other than the first RF port, wherein the first RF port is electrically coupled to the one or more selectable RF ports via metal-insulator transition material switch junctions between the first RF port and the one or more selectable RF ports, the electrically coupling comprising:
determining which of the one or more selectable RF ports to electrically couple to the first RF port;
for each selectable RF port determined to be one to electrically couple to the first RF port,
determining whether a corresponding metal-insulator transition material switch junction between the selectable RF port and the first RF port is in a conductive state or a nonconductive state, and, in response to the corresponding metal-insulator transition material switch junction being determined to be in the nonconductive state, controlling a heating element corresponding to first RF port and the selectable RF port to change the corresponding metal-insulator transition material switch junction to the conductive state that electrically couples the selectable RF port to the first RF port; and
for each selectable RF port determined not to be one to electrically couple to the first RF port,
determining whether the corresponding metal-insulator transition material switch junction between the selectable RF port and the first RF port is in the conductive state or the nonconductive state, and, in response to the corresponding metal-insulator transition material junction switch junction being in the conductive state, controlling a heating element corresponding to the first RF port and the selectable RF port to change the corresponding metal-insulator transition material switch junction to the nonconductive state that electrically decouples the selectable RF port from the first RF port.

11. The method of claim 10, wherein the controlling of the heating element comprises applying a first voltage to the heating element to change the corresponding metal-insulator transition material switch junction to the conductive state, or applying a second voltage to the heating element to change the corresponding metal-insulator transition material junction to the nonconductive state, and wherein the second voltage is reduced relative to the first voltage.

12. The method of claim 10, wherein the determining of which of the one or more selectable RF ports to electrically couple to the first RF port comprises determining that the second RF port is to electrically couple to the first RF port, wherein the heating element corresponding to first RF port and the second RF port comprises a first heating element, wherein a metal-insulator transition material switch junction corresponding to the first RF port is a first metal-insulator transition material switch junction in a first conductive state, and further comprising controlling, by the system, a second heating element corresponding to a third RF port and a fourth RF port to change a second metal-insulator transition material switch junction to a second conductive state that electrically couples the third RF port to the fourth RF port.

13. The method of claim 10, wherein a metal-insulator transition material switch junction corresponding to the first RF port is a first metal-insulator transition material switch junction in a first conductive state, wherein the electrically coupling is a first electrically coupling operation in which the determining of which of the one or more selectable RF ports to electrically couple to the first RF port comprises determining that the second RF port is to electrically couple to the first RF port, wherein, in a second electrical coupling operation, the determining of which of the one or more selectable RF ports to electrically couple to the first RF port comprises determining that the fourth RF port is to electrically couple to the first RF port, and wherein the heating element corresponding to the first RF port and the fourth RF port comprises a second heating element, and further comprising:
controlling, by the system, the first heating element corresponding to the first RF port and the second RF port to change the first metal-insulator transition material switch junction to the first nonconductive state that electrically decouples the first RF port from the second RF port, and
controlling, by the system, the second heating element to change a second metal-insulator transition material switch junction to a second conductive state that electrically couples the first RF port to the fourth RF port.

14. The method of claim 10, wherein the first RF port is an input port that obtains an input signal, and wherein the electrically coupling comprises determining at least one of the one or more selectable RF ports as at least one corresponding output port usable to obtain the input signal.

15. The method of claim 10, wherein the first RF port is an output port, and further comprising determining, by the system, a single selectable RF port of the one or more selectable RF ports to be an input port that obtains an input signal, and
wherein the electrically coupling couples the single selectable RF port to the first RF port.

16. The method of claim 10, wherein the electrically coupling is a first electrically coupling operation that:
couples the first RF port to a fourth RF port of the one or more selectable RF ports via a first metal-insulator transition material switch junction, of the metal-insulator transition material switch junctions, in a first conductive state,
decouples the first RF port from at least one of: a second RF port of the one or more selectable RF ports, or a third RF port of the one or more selectable RF ports, and
further comprising:
in a second electrically coupling operation, electrically coupling, by the system, the second RF port to the third RF port via controlling a second heating element associated with a second metal-insulator transition material switch junction, of the metal-insulator transition material switch junctions, corresponding to the second RF port and the third RF port to change the second metal-insulator transition material switch junction to a second conductive state that electrically couples the second RF port to the third RF port.

17. A multiport switch, comprising:
a group of radio frequency (RF) ports comprising a first port, a second port, a third port, and a fourth port;
respective metal-insulator transition material switches corresponding to the group of RF ports, the respective metal-insulator transition material switches comprising a first switch, a second switch, a third switch, and a fourth switch; and
a controllable heater network comprising respective heating elements that transfer heat to the respective metal-insulator transition material switches, the controllable heater network being controlled to output heat via energy to selectively determine respective lower resistance states or respective higher resistance states of the respective metal-insulator transition material switches,
wherein the controllable heater network is controlled to at least one of:
set a first switch state to electrically couple the first RF port to the second RF port;
set a second switch state to electrically couple the first RF port to the fourth RF port;
set a third switch state to electrically couple the second RF port to the third RF port; or
set a fourth switch state to electrically couple the third RF port to the fourth RF port.

18. The multiport switch of claim 17, wherein the respective metal-insulator transition material switches are arranged in a substantially rectangular pattern.

19. The multiport switch of claim 18, wherein the group of RF ports is arranged in a substantially rectangular pattern, and wherein a signal path length between any two electrically coupled RF ports is substantially equal.

20. The multiport switch of claim 17, wherein the first RF port is electrically coupled to the second RF port, and wherein the controllable heater network is further controlled to electrically decouple the first RF port from the fourth RF port.
